(19) United States
(12) Patent Application Publication
(10) Pub. No.: US 2008/0109709 A1
(43) Pub. Date: May 8, 2008

(54) Hardware-Efficient, Low-Latency Architectures for High Throughput Viterbi Decoders

(76) Inventors: Chao Cheng, Sunnyvale, CA (US); Keshab K. Parhi, Maple Grove, MN (US)

Correspondence Address: Keshab K. Parhi, 6600 Fountain Lane N., Maple Grove, MN, 55311, US

(21) Appl. No.: 11/951,822

(22) Filed: Dec. 6, 2007

Related U.S. Application Data
(63) Continuation-in-part of application No. 10/922,205, filed on Aug. 19, 2004, now Pat. No. 7,308,640.
(60) Provisional application No. 60/496,307, filed on Aug. 19, 2003.

(51) Int. Cl. H03M 13/27; G06F 11/10

(52) U.S. Cl. 714/792; 714/E11.032

(57) ABSTRACT

A low-latency, high-throughput rate Viterbi decoder implemented in a K1-nested layered look-ahead (LLA) manner, combines K1-trellis steps, with look-ahead step M, where K<K1<M, and K is the encoder constraint length. M can be an integer multiple or a non-integer multiple of one or both of K and K1. A K1-nested LLA can be implemented with any look-ahead step M. In a K1-nested LLA, look-ahead add-compare-select (ACS) computation latency increases logarithmically with respect to M/K1, and complexity of the look-ahead ACS units are controlled by adjusting K1. A K1-nested LLA can be implemented with error correction methods and systems, in communications and other systems.

### CROSS REFERENCE TO RELATED APPLICATIONS

This application is a continuation-in-part of U.S. Utility patent application Ser. No. 10/922,205, titled, “Low-Latency Architectures for High-Throughput Viterbi Decoders,” filed Aug. 19, 2004 (to issue on Dec. 11, 2007 as U.S. Pat. No. 7,308,640), which claims the benefit of U.S. Provisional Patent Application No. 60/496,307, titled, “Low-Latency Architectures for High-Throughput Viterbi Decoders,” filed on Aug. 19, 2003, both of which are incorporated herein by reference in their entirety.

### FIELD OF THE INVENTION

The present invention relates to digital communications. More specifically, the present invention relates to low latency architectures for high-throughput Viterbi decoders used in, for example and without limitation, digital communication systems, magnetic storage systems, serializer-deserializer (SERDES) applications, backplane transceivers, and high-speed wireless transceivers.

### BACKGROUND

Convolutional codes are widely used in modern digital communication systems, such as satellite communications, mobile communications systems, and magnetic storage systems. Other applications include serializer/deserializers (SERDES), backplane transceivers, and high-speed wireless transceivers. These codes provide relatively low-error rate data transmission. The Viterbi algorithm is an efficient method for maximum-likelihood (ML) decoding of convolutional codes.

In hardware implementation, a conventional Viterbi decoder is composed of three basic computation units: branch metric unit (BMU), add-compare select unit (ACSU), and survivor path memory unit (SMU). The BMU and the SMU are only composed of feed-forward paths. It is relatively easy to shorten the critical path in these two units by utilizing pipelining techniques. However, the feedback loop in the ACS unit is a major bottleneck for the design of a high-speed Viterbi decoder. A look-ahead technique, which combines several trellis steps into one trellis step in time sequence, has been used for breaking the iteration bound of the Viterbi decoding algorithm. One iteration in an M-step look ahead ACS unit is equivalent to M iterations in the non-look-ahead or sequential implementation. Thus, the speed requirement on the ACS unit for a given decoding data rate is reduced by M times. However, the total number of parallel branch metrics in the trellis increases exponentially as M increases linearly. On the other hand, the latency of the ACS pre-computation is relatively long due to the M-step look-ahead, especially when M is large. Generally, the ACS pre-computation latency increases linearly with respect to M.

What are needed are methods and systems to reduce the complexity and latency of the ACS pre-computation part in high-throughput Viterbi decoders.

### BRIEF SUMMARY OF THE INVENTION

Convergence of parallel trellis paths of length-K, where K is the encoder constraint length, is taught in U.S. Pat. No. 7,308,640, titled, “Low-Latency Architectures for High-Throughput Viterbi Decoders,” issued Dec. 11, 2007, to Parhi, et. al., and U.S. Provisional Patent Application No. 60/496,307, titled, “Low-Latency Architectures for High-Throughput Viterbi Decoders,” filed on Aug. 19, 2003, incorporated herein by reference above (hereinafter, the “'640 patent” and the “'307 application,” respectively).

The '640 patent and the '307 application teach to combine K trellis steps in a first layer into M/K sub-trellis steps, and to combine the resulting sub-trellises in a tree structure. This K-nested layered M-step look-ahead (LLA) method can efficiently reduce latency.

Disclosed herein are methods and systems that combine K1 trellis steps in a first layer of a K-nested layered M-step Viterbi decoder, where K≦K1<M. Parallel paths exist when K1≧K. Thus, ACS-pre-computation of K1 stages can be combined in the first layer. Although the increased look-ahead steps in the first layer may increase latency in the first layer, the total number of layers can be reduced, thus decreasing the overall latency. A K1-nested LLA, as disclosed herein, can be implemented to reduce hardware complexity, for example, when K is relatively large.

Further embodiments, features, and advantages of the present invention, along with structure and operation of various embodiments of the present invention, are discussed in detail below with reference to the accompanying figures.

### BRIEF DESCRIPTION OF THE DRAWINGS/FIGURES

The present invention is described with reference to the accompanying figures. The accompanying figures, which are incorporated herein and form part of the specification, illustrate the present invention and, together with the description, further serve to explain the principles of the invention and to enable a person skilled in the relevant art to make and use the invention.

FIGS. 1A and 1B illustrate trellis diagrams of a conventional M-step look-ahead decoder for an encoder constraint length, K, where K=3, and M=2.

FIGS. 2A and 2B illustrate trellis diagrams of a conventional M-step look-ahead decoder for an encoder constraint length, K, where K=3, and M=3.

FIGS. 3A and 3B illustrate trellis diagrams of a conventional M-step look-ahead decoder for an encoder constraint length, K, where K=3, and M=4.

FIGS. 4A and 4B illustrate an alternative representation of trellis diagrams of a conventional M-step look-ahead decoder for an encoder constraint length, K, where K=3, and M=4.

FIGS. 5A and 5B illustrate trellis diagrams of a conventional M-step look-ahead decoder for an encoder constraint length, K, where K=3, and M>3.

FIG. 6 illustrates an exemplary method of combining parallel paths after layer 1, for a K-nested layered look-ahead decoding process.

FIGS. 7A and 7B illustrate exemplary trellis diagrams for a K1-nested layered look-ahead decoding process, for an encoder constraint length, K, where K=3, K1=6, and M=12.

FIGS. 8A, 8B, 8C, and 8D illustrate exemplary trellis diagrams for a K1-nested layered look-ahead decoding process, for an encoder constraint length, K, where K=3, K1=4, and M=27.

FIGS. 9A, 9B, and 9D illustrate exemplary trellis diagrams for a K1-nested layered look-ahead decoding process, for an encoder constraint length, K, where K=3, K1=4, and M=11.

FIGS. 10A and 10B illustrate exemplary trellis diagrams for a K1-nested layered look-ahead decoding process, for an encoder constraint length, K, where K=3, K1=6, and M=1.

### DETAILED DESCRIPTION OF THE INVENTION

### I. M-Step Look-Ahead Viterbi Decoding

In conventional M-step look-ahead Viterbi decoding, M look-ahead steps are performed to move the combined branch metrics computation outside of the ACS recursion loop. This allows the ACS loop to be pipelined or computed in parallel. Thus, the decoding throughput rate can be increased.

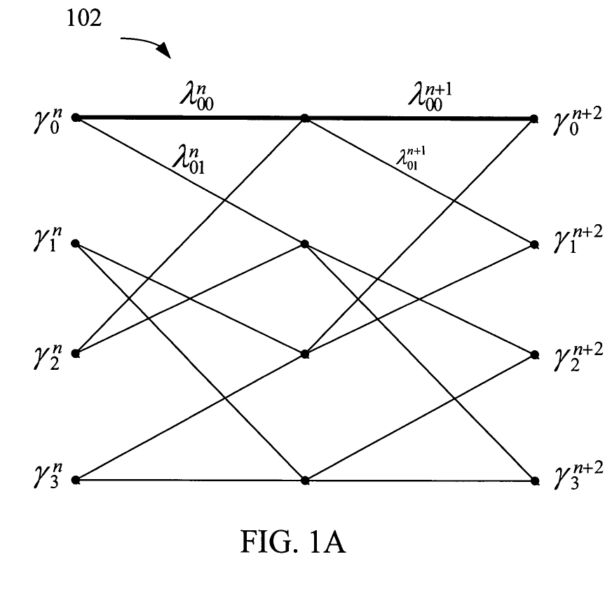

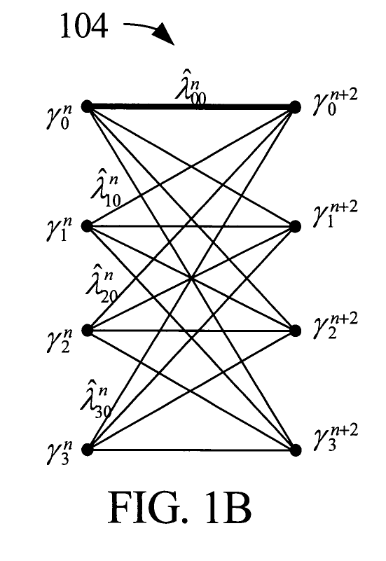

FIGS. 1A and 1B illustrate exemplary trellis diagrams for a conventional M-step look-ahead Viterbi decoder, where the constraint length, K, of the convolutional code is 3, and the look-ahead step, M, is 2. The number of states can be calculated as 2^{K-1}=4.

FIG. 1A illustrates a trellis diagram 102, which is obtained by performing 2-step look-ahead. In the figure, branch metric from state i to state i at step n is denoted as λᵢⱼⁿ, and similarly, branch metric from state i to state j at step n+1 is denoted as λᵢⱼⁿ⁺¹. Path metric for state i at step n is denoted as λᵢⁿ. After the 2-step look-ahead operation, each state at step n+2 can be reached by all four states at step n.

FIG. 1B illustrates a resulting 2-step look-ahead trellis 104. The new branch metric from state i to state j in the resulting 2-step look-ahead trellis diagram 104 can be computed by adding the two connected branch metrics from state i to state j in the trellis diagram 102 (FIG. 1A). For example, branch metric from state 0 at step n to state 0 at step n+2 in the 2-step look-ahead trellis diagram is computed as:
\hat{λ}₀₀ⁿ=λ₀₀ⁿ+λ₀₀ⁿ⁺¹ EQ. (1)

Compared with the original trellis diagram 102 in FIG. 1A, the ACS unit at each state in FIG. 1B needs to choose the final path metric from four paths. For example, when the path metric with the maximum value is selected as the survivor path:
γ₀ⁿ⁺²=max{γ₀ⁿ+\hat{λ}₀₀ⁿ,γ₁ⁿ+\hat{λ}₁₀ⁿ,γ₂ⁿ+\hat{λ}₂₀ⁿ,γ₃ⁿ+\hat{λ}₃₀ⁿ} EQ. (2)

The number of required 2-input adders and compare-select (CS) units for this example are 2^{K-1}×2^{K-1} and 2^{K}×(2^{K-1}−1), respectively.

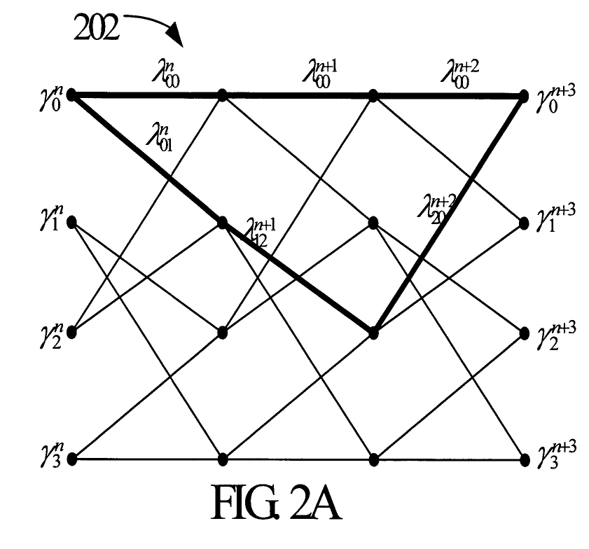

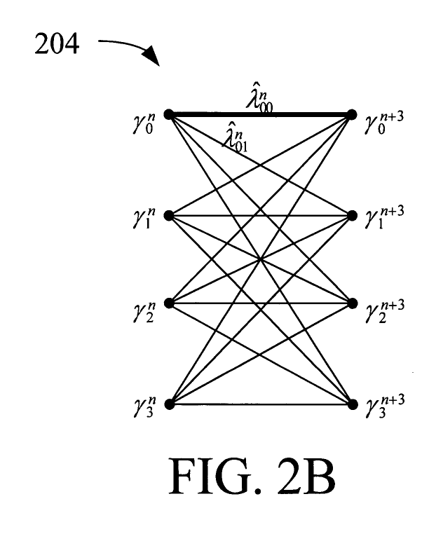

FIGS. 2A and 2B illustrate exemplary trellis diagrams for a conventional M-step look-ahead Viterbi decoder, where the constraint length of the convolutional code K is 3, and the look-ahead step M is 3. FIG. 2A illustrates trellis diagram 202, which is obtained by performing 3-step look-ahead. There are two parallel paths starting from state 0 at step n to state 0 at step n+3 as M=K.

FIG. 2B illustrates resulting trellis diagram 204 after a 3-step look-ahead operation. The new branch metric \hat{λ}₀₀ⁿ in FIG. 2B is selected from two parallel accumulated branch metrics {λ₀₀ⁿ+λ₀₀ⁿ⁺¹+λ₀₀ⁿ⁺²,λ₀₁ⁿ+λ₁₂ⁿ⁺¹+λ₂₀ⁿ⁺²}. Other branch metrics in the resulting 3-step look-ahead trellis diagram 204 can be obtained by using similar methodology. The number of required 2-input adders and CS units are 2^{K-1}×(2²+2^{K}) and 2^{K-1}×2^{K-1}, respectively. The latency in this example is K=3 clock cycles.

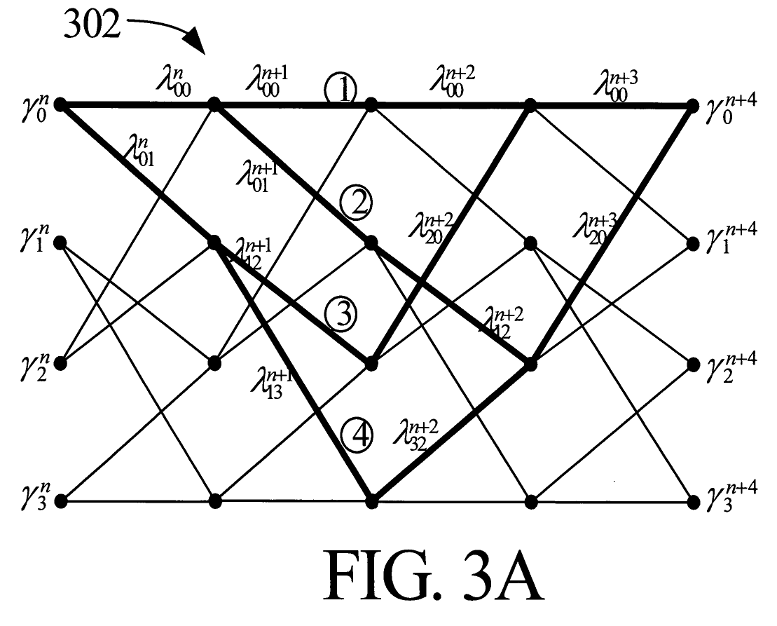

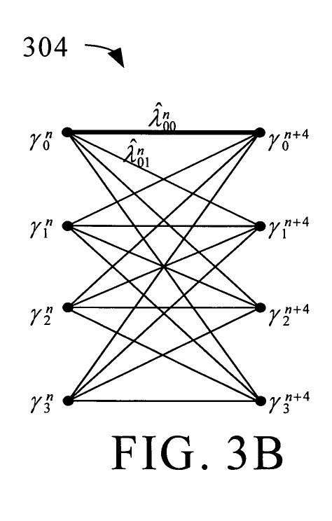

FIGS. 3A and 3B illustrate exemplary trellis diagrams for an example conventional M-step look-ahead Viterbi decoder, where the constraint length of the convolutional code K is 3, and the look-ahead step M is 4. FIG. 3A illustrates a trellis diagram 302, which is obtained by performing 4-step look-ahead. There are 2^{M-K+1}=4 parallel paths, 1, 2, 3, and 4, starting from state 0 at step n to state 0 at step n+4. FIG. 3B illustrates a resulting trellis diagram 304 after the 4-step look-ahead operation. The new branch metric \hat{λ}₀₀ⁿ in FIG. 3B is selected from four parallel accumulated branch metrics:
{λ₀₀ⁿ+λ₀₀ⁿ⁺¹+λ₀₀ⁿ⁺²λ₀₀ⁿ⁺³,λ₀₁ⁿ+λ₁₂ⁿ⁺¹+λ₂₀ⁿ⁺²λ₀₀ⁿ⁺³,λ₀₀ⁿ+λ₀₁ⁿ⁺¹+λ₁₂ⁿ⁺²+λ₂₀ⁿ⁺³,λ₀₁ⁿ+λ₁₃ⁿ⁺¹+λ₃₂ⁿ⁺²+λ₂₀ⁿ⁺³}

Other branch metrics in the resulting 4-step look-ahead trellis diagram can be obtained by using similar methodology.

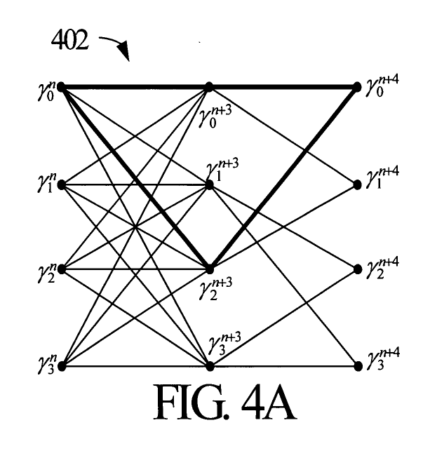

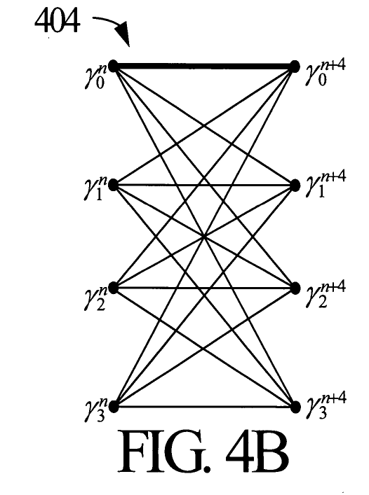

FIGS. 4A and 4B illustrate exemplary trellis diagrams for a conventional Viterbi decoder method in which a 3-step look ahead operation is performed, resulting in trellis diagram 402 in FIG. 4A, followed by a 4-step look ahead operation performed on results of the 3-step look ahead operation, resulting in trellis diagram 404 in FIG. 4B. In the trellis diagram 402 of FIG. 4A, there are two parallel paths starting from state 0 at step n to state 0 at step n+4. The resulting 4-step look-ahead trellis diagram 402 is the same as the resulting trellis diagram 312 in FIG. 3B. The number of required 2-input adders and CS units for the examples of FIGS. 3B and 4B are 2^{K-1}×(2²+2^{K})+2^{K-1}×2^{K-1}×2 and 2^{K-1}×2^{K-1}+2^{K-1}×2^{K-1}, respectively. The latency for these examples is K+2=5 clock cycles.

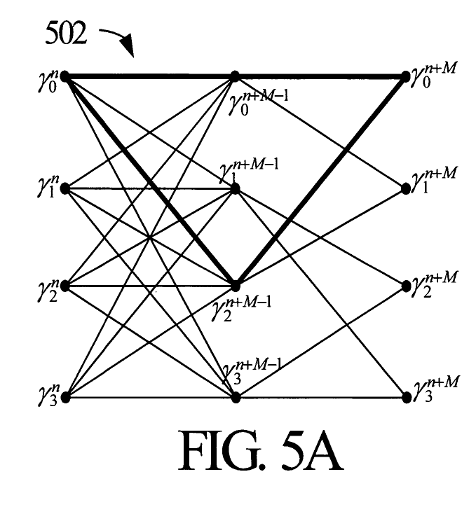

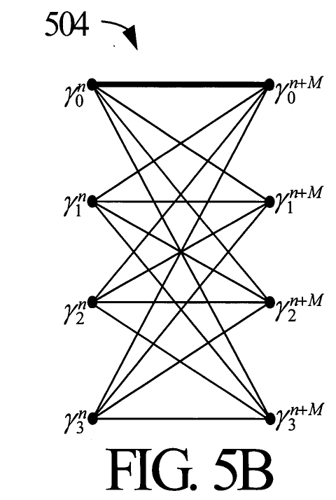

In general, where K=3, and M>3, using similar strategy as in the example of FIGS. 4A and 4B, M-step look-ahead operation can be achieved by first performing M-1-step look-ahead, and then performing one-step look-ahead. FIG. 5A illustrates this process with an exemplary trellis diagram 502, where there are two parallel paths starting from state 0 at step n to state 0 at step n+M. FIG. 5B illustrates an exemplary resulting M-step look-ahead trellis diagram 504. The number of required 2-input adders and CS units for the trellis diagram 504 are 2^{K-1}×4×(2^{K-2}−1)+2^{K-1}×2^{K}×(M−K+1) and 2^{K-1}×2^{K-1}×(M−K+1), respectively. The latency is K+2×(M−K)=2M−K clock cycles.

Hardware costs for a conventional M-step look-ahead technique are in the order of O((2^{K-1}))²=O(4^{K}), and increase with the look-ahead step M. On the other hand, the latency of the resulting Viterbi decoder increases linearly as M increases. For a high-throughput Viterbi decoder, the look-ahead step M is usually very large. The long latency associated with a high-throughput Viterbi decoder is a drawback. Thus, it would be useful to reduce the latency when M is very large.

### II. K-Nested Layered M-Step Look-Ahead (K-Nested LLA) Techniques

The '640 patent and the '307 application, incorporated by reference above, teach to combine K trellis steps in a first layer into M/K sub-trellis steps, and to combine the resulting sub-trellises into a tree structure. Unlike conventional M-step look-ahead methods, the LLA method first combines M steps into M/K groups, and performs K-step look-ahead in parallel for all M/K groups. The resulting M/K sub-trellises are then combined in a tree structure, or a layered manner. The K-nested layered M-step look-ahead (LLA) method can efficiently reduce latency, for example, when M is relatively large.

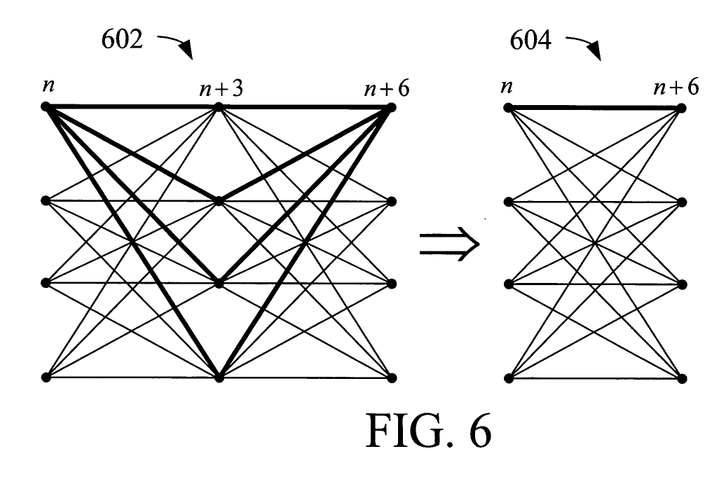

FIG. 6 illustrates exemplary M/K sub-trellis diagrams 602 and 604, for performing K-step look-ahead in parallel, for K=3 and M=6. It can be seen that each sub-trellis is fully connected. Thus, any state at a current step in the sub-trellis can connect with any state at the next step. Combining the two sub-trellis diagrams together results in four parallel paths starting from state 0 at step n to state 0 at step n+6, as shown at 602. Resulting trellis 604 is obtained by combining two sub-trellises together. In a similar manner, the M/K sub-trellises can be combined into a tree structure such that the latency does not increase linearly with M. The latency of the K-nested layered M-step look-ahead (LLA) method is given as:

$$\begin{matrix}{L}_{kong} = {L}_{kong\_add} + {L}_{CS\_radix - 2} + ( {log}_{2} ( M / K ) ) \cdot \\ {L}_{CS\_radix - {2}^{K - 1}} \\ = ( ( K - 1 ) + {log}_{2} ( M / K ) ) + 1 + ( {log}_{2} ( M / K ) ) \cdot \\ {L}_{CS\_radix - {2}^{K - 1}} \\ = K + K \cdot {log}_{2} ( M / K )\end{matrix} \qquad EQ . ( 3 )$$

where L_{kong}_{_{—}}_{add} is the latency of 2-input adders used in an ACS pre-computation. L_{CS}_{_{—}}_{radix-2} is the latency of radix-2 compare-select units in the ACS pre-computation. L_{CS}_{_{—}}_{radix-2}_{^{K−1}} is the latency of radix-2 k−1 compare-select units in the ACS pre-computation. The ACS pre-computation latency thus increases logarithmically with respect to M/K. If M/K is not a power-of-two, ┌log₂(M/K)┐ is used for latency calculation instead of log₂ (M/K). Where the function ┌x┐ is the smallest integer greater than or equal to x.

The methods and systems taught in the '640 patent and the '307 application are suitable for many applications. Disclosed herein are methods and systems that reduce hardware complexity, for example, when K is relatively large, and that reduce ACS pre-computation latency for essentially any level of parallelism, M, including when M is a non-integer multiple of the encoder constraint length K.

### III. K1-Nested Layered M-Step Look-Ahead (K1-Nested LLA) Techniques

As described above, the number of parallel paths from one state to the same state is 2^{M-K-1} for an M-step conventional look-ahead. Thus, parallel paths exist when the look-ahead step is larger than the encoder constraint length K. In addition, the resulting trellis diagram is fully connected when M>K. This makes it possible to combine the resulting sub-trellises into a tree structure.

As disclosed herein, K-nested layered M-step look-ahead (LLA) techniques are implemented with a look-ahead step K1, where K≦K1≦M, and where M can be an integer multiple of K and/or K1, or can be a non-integer multiple of K and/or K1. The look-ahead step M is effectively decomposed into

$$⌊ \frac{M}{K 1} ⌋$$

groups combined with K1 steps, and, where M is not an integer multiple of K1, a remainder group combined with mod (M, K1) steps. The notation mod (M, K1) represents the remainder of dividing M by K1. The resulting

$$⌊ \frac{M}{K 1} ⌋ + 1$$

sub-trellises are then combined into a tree structure.

The methods and systems disclosed herein can be applied to high-throughput Viterbi decoding for any M greater than K. Increasing the look-ahead step from K to K1 will typically increase the latency in the first layer. However, the number of sub-trellises is also reduced due to the increased look-ahead step K1 in the first layer. Thus, the overall latency of M-step look-ahead can be reduced. The overall hardware complexity is controllable by adjusting K1. Example embodiments are provided below. The invention is not, however, limited to the examples herein.

### A. EXAMPLE 1

### K=3, M=12, and K1=6

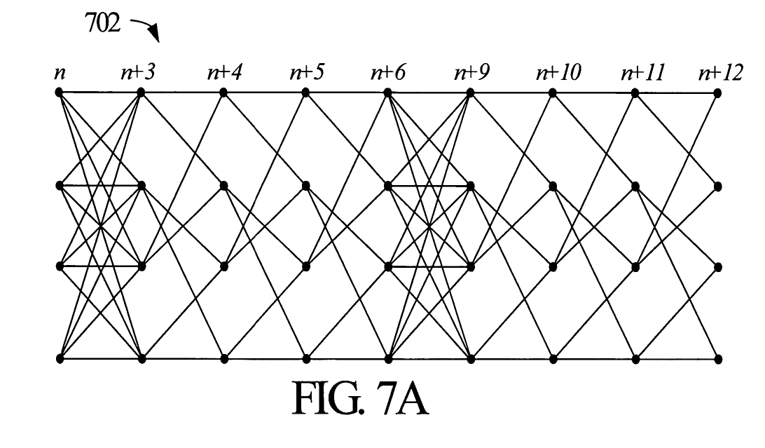

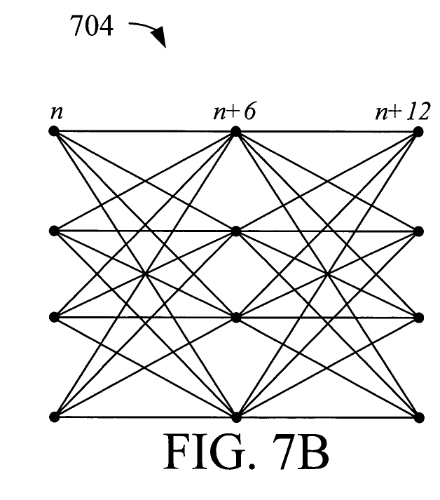

In this example, M is a multiple of K1. M can thus be decomposed into 2 groups, and each group is combined with K1 steps. FIG. 7A illustrates a trellis diagram 702 (layer 1) combining K1 steps in each group. FIG. 7B illustrates resulting combined 2 sub-trellises 704 (layer 2).

Table I summarizes hardware complexity and latency for example 1, compared with a conventional design and a K-nested LLA implementation as taught in the '640 patent and the '307 application. It can be seen that the K1-nested LLA implementation of example 1 utilizes 64 fewer adders than the K-nested LLA implementation. Although latency of example 1 is 3 clock cycles greater that the K-nested LLA implementation, it is significantly less than a conventional implementation.

TABLE I
Summary for the case of K = 3, K1 = 6, and M = 12

| | K1-nested LLA | | |
|---|---|---|---|
| | (K1 = 6) | Conventional | K-nested LLA |
| Latency | 12 | 21 | 9 |
| 2-input adders | 528 | 496 | 592 |

### B. EXAMPLE 2

### K=3, M=27 and K1=4

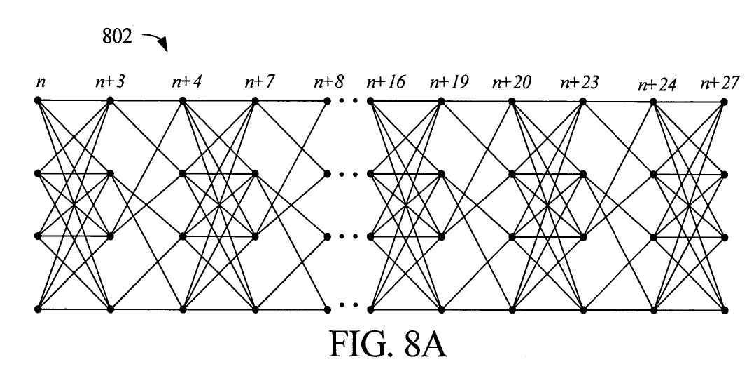

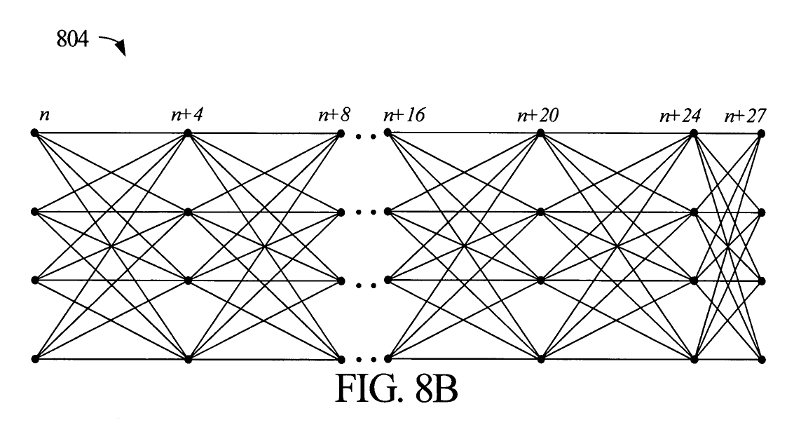

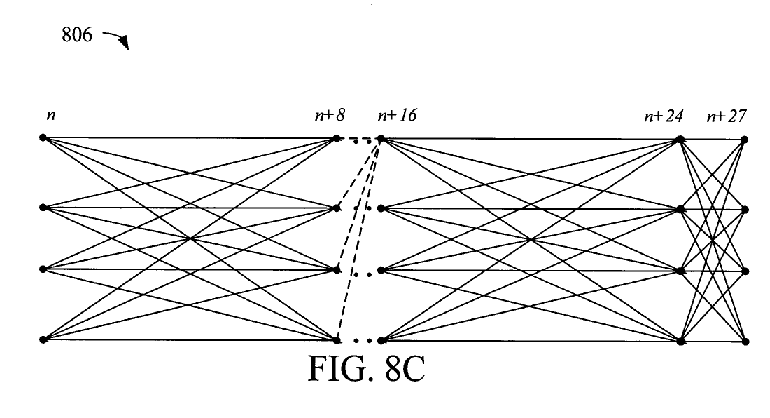

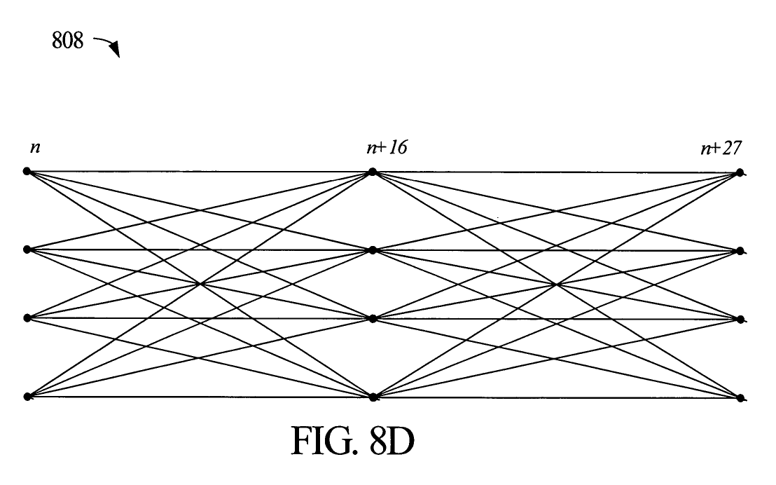

In this example, M is a multiple of K, but not a multiple of K1. FIG. 8A illustrates a trellis diagram 802 of the first layer. FIG. 8B illustrates resulting sub-trellises 804 (layer 2). There are

$$⌊ \frac{M}{K 1} ⌋ = 6$$

sub-trellises obtained by performing K1-step look-ahead and a remainder sub-trellis obtained by performing 3-step look-ahead, as mod (M, K1)=3. Continuing to combine these sub-trellises in a tree manner provides the trellis diagrams 806 (layer 3) and 804 (layer 4) shown in FIGS. 8C and 8D, respectively.

Table II summarizes hardware complexity and latency for example 2, compared with a conventional design and a K-nested LLA implementation. It can be seen that the K1-nested LLA example 2 utilizes 64 fewer adders than the K-nested LLA implementation. In addition, latency is reduced by 1 clock cycle.

TABLE II
Summary for the case of K = 3, K1 = 4, and M = 27

| | K1-nested LLA | | |
|---|---|---|---|
| | (K1 = 4) | Conventional | K-nested LLA |
| Latency | 14 | 51 | 15 |
| 2-input adders | 1408 | 1216 | 1472 |

### C. EXAMPLE 3

### K=3, M=11 and K1=4

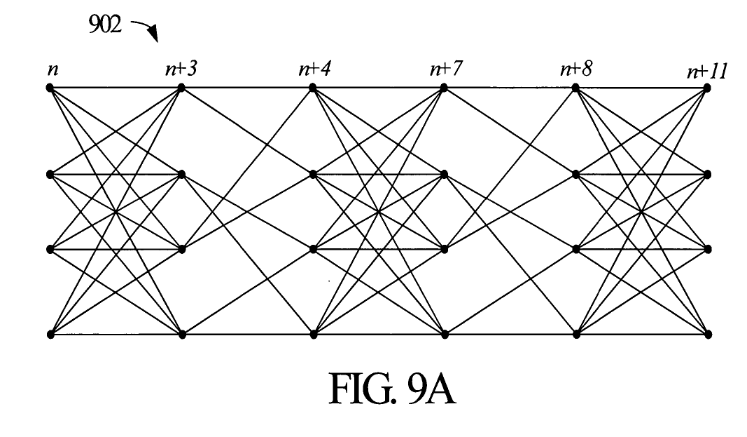

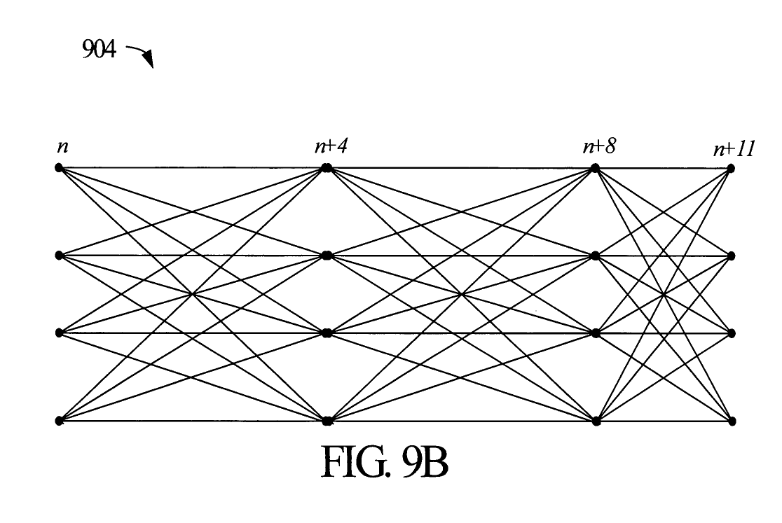

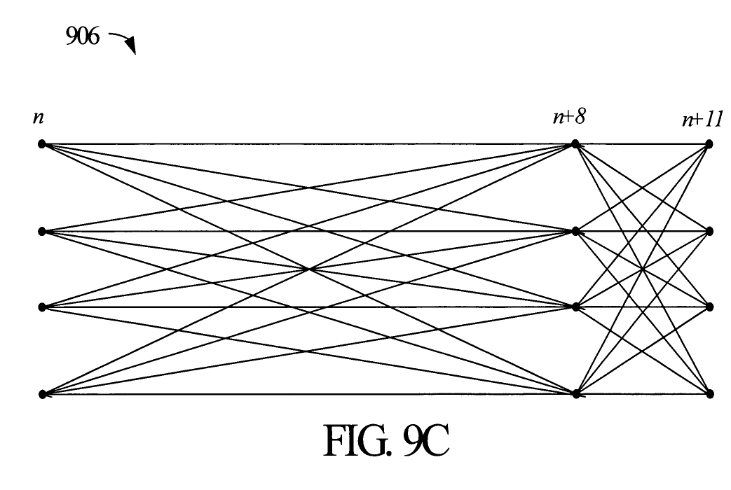

In this example, M is neither a multiple of K nor of K1. FIG. 9A illustrates a trellis diagram 902 of the first layer. FIG. 9B illustrates resulting sub-trellises 902 (layer 2). There are

$$⌊ \frac{M}{K 1} ⌋ = 2$$

sub-trellises obtained by performing K1-step look-ahead and a remainder sub-trellis obtained by performing 3-step look-ahead, as mod (M, K1)=3. Combining these sub-trellises in a tree manner leads to trellis diagram 906 (layer 3) shown in FIG. 9C.

### D. EXAMPLE 4

### K=3, M=11 and K1=6

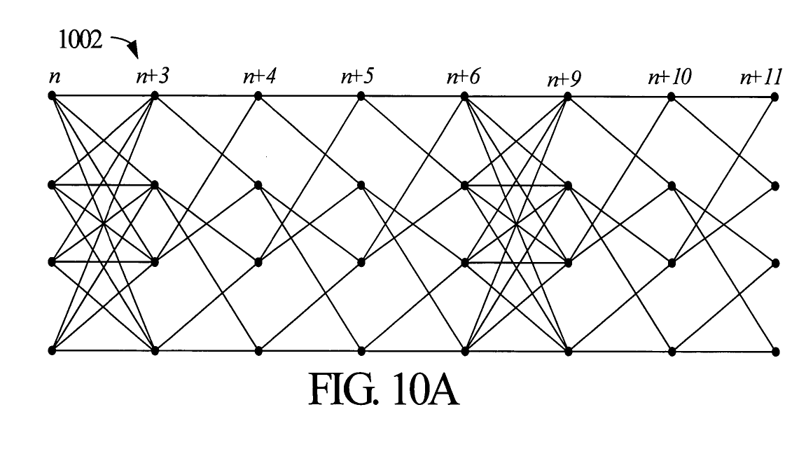

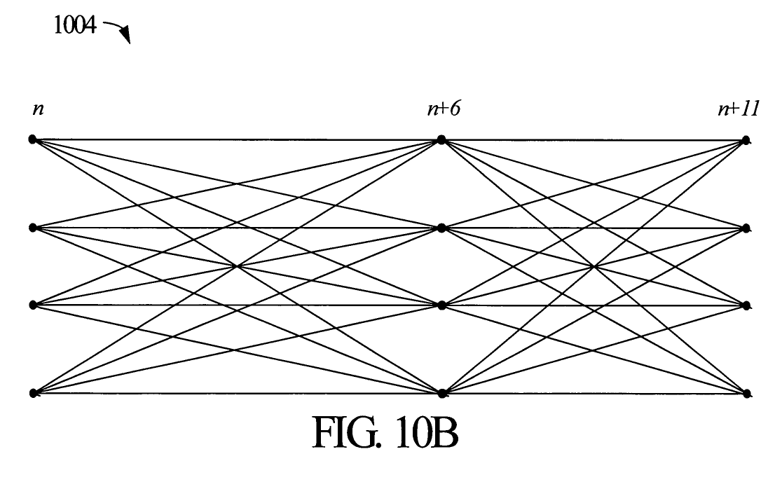

FIG. 10A illustrates a trellis diagram 1002 of the first layer for example 4. FIG. 10B illustrates resulting sub-trellises 1004 (layer 2). There are

$$⌊ \frac{M}{K 1} ⌋ = 1$$

sub-trellis obtained by performing K1-step look-ahead and a remainder sub-trellis obtained by performing 5-step look-ahead, as mod (M, K1)=5.

Examples 3 and 4 illustrate the effect of K1on the overall complexity and latency. Table III summarizes hardware complexity and latency for examples 3 and 4, compared with a conventional design. It can be seen that by increasing K1, the overall hardware cost is reduced while latency increases. Thus, optimum K1 can be selected according to different system requirements on latency and hardware cost.

TABLE III
Summary for the case of K = 3 and M = 11

| | K1-nested LA | K1-nested LLA | |
|---|---|---|---|
| | (K1 = 4) | (K1 = 6) | Conventional |
| Latency | 11 | 12 | 19 |
| 2-input adders | 512 | 480 | 448 |

### E. HARDWARE AND LATENCY CALCULATIONS

In general, for a high-throughput Viterbi decoder design with M-step look-ahead, the hardware complexity of a K1-nested LLA architecture can be computed as:

$${C}_{Proposed} = {C}_{add\_ 1 st} + {C}_{add\_ 2 \_last} + {C}_{CS\_ 1 st} + {C}_{CS\_ 2 \_last} \\ where , \\ {C}_{add\_ 1 st} = \{ \begin{matrix}{2}^{K - 1} ⨯ [ 4 ⨯ ( {2}^{K - 1} - 1 ) + {2}^{K - 1} ⨯ 2 ⨯ ( K 1 - K ) ] ⨯ \frac{M}{K 1} , & when mod ( M , K 1 ) = 0 \\ {2}^{K - 1} ⨯ [ 4 ⨯ ( {2}^{K - 1} - 1 ) + {2}^{K - 1} ⨯ 2 ⨯ ( K 1 - K ) ] ⨯ ⌊ \frac{M}{K 1} ⌋ + , & when mod ( M , K 1 ) \geq K \\ {2}^{K - 1} ⨯ [ 4 ⨯ ( {2}^{K - 1} - 1 ) + {2}^{K - 1} ⨯ 2 ⨯ ( mod ( M , K 1 ) - K ) ] & \end{matrix} \\ {C}_{add\_ 2 \_last} = {2}^{K - 1} ⨯ {( {2}^{K - 1} )}^{2} ⨯ ( ⌈ \frac{M}{K 1} ⌉ - 1 ) , \\ {C}_{CS\_ 2 \_last} = {( {2}^{K - 1} )}^{2} ⨯ ( ⌈ \frac{M}{K 1} ⌉ - 1 ) ⨯ ( {2}^{K - 1} - 1 ) , \\ {C}_{CS\_ 1 st} = \{ \begin{matrix}{( {2}^{K - 1} )}^{2} ⨯ ( K 1 - K + 1 ) ⨯ \frac{M}{K 1} , & when mod ( M , K 1 ) = 0 \\ {( {2}^{K - 1} )}^{2} ⨯ ( K 1 - K + 1 ) ⨯ ⌊ \frac{M}{K 1} ⌋ + {( {2}^{K - 1} )}^{2} ⨯ [ mod ( M , K 1 ) - K + 1 ] , & when mod ( M , K 1 ) \geq K\end{matrix} \qquad EQ . ( 4 )$$

The latency of the ACS pre-computation for the K1-nested LLA architecture can be computed as:

$${L}_{proposed} = K + 2 ⨯ ( K 1 - K ) + K ⨯ ⌈ {log}_{2} ( \frac{M}{K 1} ) ⌉ \qquad EQ . ( 5 )$$

An example comparison between a K-nested LLA implementation and a K1-nested LLA implementation is provided below for a 4-state 10 Gigabit/second serializer/deserializer (SERDES), having a latency requirement of less than 60 ns. A K-nested LLA architecture, implemented with 0.13-um technology, and 48-stage ACS pre-computation, has a latency of 15×1.5=22.5 ns. A K1-nested LLA architecture, implemented with 0.13-um technology, has an ACS pre-computation latency of 18×1.5=27 ns. Both implementations meet the latency requirement, while the K1-nested LLA reduces hardware complexity by 9.47%.

### IV. Conclusion

While various embodiments of the present invention have been described above, it should be understood that they have been presented by way of example only, and not limitation. It will be understood by those skilled in the art that various changes in form and details can be made therein without departing from the spirit and scope of the invention as defined in the appended claims. Thus, the breadth and scope of the present invention should not be limited by any of the above-described exemplary embodiments, but should be defined only in accordance with the following claims and their equivalents.

What is claimed is:

1. A method of combining M trellis steps of a trellis generated by a convolutional decoder having (K−1) memory elements, implemented in one or more of a circuit and a computer program, comprising:
separating the M trellis steps into one or more sets of K1 trellis steps, wherein K1 is an integer and K<K1<M;
performing initial add-compare-select pre-computations on branch metrics of each set of trellis steps;
performing one or more subsequent add-compare-select pre-computations on sets of results of preceding add-compare-select pre-computations in a layered manner;
performing an add-compare-select recursion operation on a final result of the one or more subsequent add-compare-select pre-computations and on a result of a prior add-compare-select recursion operation; and
generating decoded information from survivor path information associated with the one or more subsequent add-compare-select pre-computations under control of results of the add-compare-select recursion operation.

2. The method according to claim 1, wherein M is an integer multiple of K1.

3. The method according to claim 1, wherein M is a non-integer multiple of K1, and wherein the separating comprises separating the M trellis steps into one or more sets of K1 trellis steps and into a remainder of M/K1 set of the M trellis steps.

4. The method according to claim 1, wherein M is a non-integer multiple of K.

5. The method according to claim 1, wherein the performing of the initial add-compare-select pre-computations includes performing a plurality of additions and one add-compare-select pre-computation operation for each of the one or more sets of trellis steps.

6. The method according to claim 1, further comprising performing the subsequent add-compare-select pre-computations on pairs of results of preceding add-compare-select pre-computations.

7. The method according to claim 6, further comprising performing the subsequent add-compare-select pre-computations for an unpaired output of an immediately preceding layer of add-compare-select pre-computations and an unpaired output of a previously preceding layer of add-compare-select pre-computations.

8. The method according to claim 1, further comprising performing the subsequent add-compare-select pre-computations using at least
$$⌈ {log}_{2} ( \frac{M}{K 1} ) ⌉$$
intermediate add-compare-select circuits connected in a pipelined layered configuration including a first layer of intermediate add-compare-select circuits having branch metric inputs coupled to outputs of initial add-compare-select circuits and one or more subsequent layers of intermediate add-compare-select circuits having branch metric inputs coupled to outputs of intermediate add-compare-select circuits in one or more previous layers;
wherein the function
$$⌈ {log}_{2} ( \frac{M}{K 1} ) ⌉$$
is a smallest integer greater than or equal to
$${log }_{2} ( \frac{M}{k 1} ) .$$

9. The method of claim 1, wherein the performing of the initial add-compare-select pre-computations includes combining each set of trellis steps into one trellis step and selecting a maximum likely trellis path from a plurality of parallel paths within each set of trellis steps.

10. The method of claim 1, wherein the performing of the subsequent add-compare-select pre-computations includes combining two branch metrics resulting from the initial add-compare-select pre-computations and selecting a maximum likely trellis path from a plurality of parallel trellis paths.

11. A circuit that combines M trellis steps of a trellis generated by a convolutional code encoder containing (K−1) memory elements, comprising:
an M-input initial add-compare-select circuit including └M/K1┘ initial add-compare-select circuits each having K1 branch metric inputs, wherein └M/K1┘ represents an integer portion of M/K1, wherein K1 is an integer, and wherein K<K1<M;
one or more layers of intermediate add-compare-select circuits, including a first layer of one or more add-compare-select circuits having inputs coupled to outputs of the M-input initial add-compare-select circuit and a final layer add-compare-select circuit;
an add-compare-select recursion circuit having a first input coupled to an output of the final layer intermediate add-compare-select circuit and a second input coupled to an output of the add-compare-select recursion circuit; and
a survivor path management circuit coupled to one or more of the intermediate add-compare-select circuits and to the add-compare-select recursion circuit.

12. The circuit of claim 11, wherein M is an integer multiple of K1.

13. The circuit of claim 11, wherein M is a non-integer multiple of K1, and wherein the M-input initial add-compare-select circuit includes a remainder initial add-compare-select circuit having a remainder of M/K1 inputs.

14. The circuit of claim 11, wherein M is a non-integer multiple of K.

15. The circuit of claim 11, wherein each of the initial add-compare-select circuits include a plurality of adder circuits and one add-compare-select circuit.

16. The circuit of claim 11, wherein the one or more layers of intermediate add-compare-select circuits include at least
$$⌈ {log}_{2} ( \frac{M}{K 1} ) ⌉$$
intermediate add-compare-select circuits connected in a pipelined layered configuration including a first layer of intermediate add-compare-select circuits having branch metric inputs coupled to outputs of the initial add-compare-select circuits and one or more subsequent layers of intermediate add-compare-select circuits having branch metric inputs coupled to outputs of intermediate add-compare-select circuits in one or more preceding layers; and
wherein the function
$$⌈ {log}_{2} ( \frac{M}{K 1} ) ⌉$$
is a smallest integer greater than or equal to
$${log }_{2} ( \frac{M}{K 1} ) .$$

17. The circuit of claim 11, wherein each of the initial add-compare-select circuits is configured to combine the corresponding set of trellis steps into one trellis step and to select a maximum likely trellis path from a plurality of parallel paths with the set of trellis steps.

18. The circuit of claim 11, wherein each of the intermediate add-compare-select circuit is configured to combine two branch metrics generated by the initial add-compare-select circuits and to select a maximum likely trellis path from a plurality of parallel trellis paths.

19. A method of combining M trellis steps of a trellis generated by a convolutional decoder having (K−1) memory elements, implemented in one or more of a circuit and a computer program, comprising:
receiving branch metrics associated with the M trellis steps;
selecting a maximum likely trellis path from a plurality of parallel trellis paths for each of one or more sets of K1of the M trellis steps, wherein K1 is an integer and K<K1<M;
selecting a maximum likely trellis path from a plurality of parallel trellis paths for each of one or more sets of previously selected maximum likely trellis paths, until a final maximum likely trellis path is selected;
generating survivor path information corresponding to the selection of a maximum likely trellis path;
performing a recursion operation on the final selected maximum likely trellis path and on a result of a prior recursion operation; and
generating decoded information from survivor path information corresponding to the final maximum likely trellis path, under control of results of the recursion operation.

20. The method according to claim 19, wherein M is an integer multiple of K1.

21. The method according to claim 19, wherein M is a non-integer multiple of K1, and wherein the selecting comprises selecting a maximum likely trellis path from a plurality of parallel trellis paths for each of one or more sets of K1of the M trellis steps, and for a remainder of M/K1 set of the M trellis steps when M is a non-integer multiple of K1.

22. The method according to claim 19, wherein M is a non-integer multiple of K.

23. A circuit that combines M trellis steps of a trellis generated by a convolutional decoder having (K−1) memory elements, comprising:
an M-input initial maximum likely trellis path selection circuit including └M/K1┘ initial maximum likely trellis path selection circuits each having K1 branch metric inputs, wherein └M/K1┘ represents an integer portion of M/K1, wherein K1 is an integer, and wherein K<K1<M;
one or more layers of intermediate maximum likely trellis path selection circuits, including a first layer of one or more maximum likely trellis path selection circuits having inputs coupled to outputs of the M-input initial maximum likely trellis path selection circuit and a final layer maximum likely trellis path selection circuit;
an maximum likely trellis path selection recursion circuit having a first input coupled to an output of the final layer intermediate maximum likely trellis path selection circuit and a second input coupled to an output of the maximum likely trellis path recursion circuit; and
a survivor path management circuit coupled to one or more of the intermediate maximum likely trellis path selection circuits and to the maximum likely trellis path selection recursion circuit.

24. The circuit of claim 23, wherein M is an integer multiple of K1.

25. The circuit of claim 23, wherein M is a non-integer multiple of K1, and wherein the M-input initial maximum likely trellis path selection circuit includes a remainder initial maximum likely trellis path selection circuit having a remainder of M/K1 inputs.

26. The circuit of claim 23, wherein M is a non-integer multiple of K.
